(19) United States
(12) Patent Application Publication
(10) Pub. No.: US 2024/0087600 A1
(43) Pub. Date: Mar. 14, 2024

(54) MAGNETIC DISK DEVICE AND REFRESH PROCESSING METHOD

(71) Applicants: Kabushiki Kaisha Toshiba, Tokyo (JP); Toshiba Electronic Devices & Storage Corporation, Tokyo (JP)

(72) Inventor: Akihiro HARIGAE, Yokohama Kanagawa (JP)

(21) Appl. No.: 18/182,693

(22) Filed: Mar. 13, 2023

(30) Foreign Application Priority Data
Sep. 14, 2022 (JP) 2022-146348

(51) Int. Cl. G11B 5/55

(52) U.S. Cl. CPC G11B 5/5526

(57) ABSTRACT

According to one embodiment, a magnetic disk device includes a disk, a first head, and a control unit. The control unit includes an adjustment unit capable of adjusting k1, a counter, a determination unit, and a refresh processing unit. The adjustment unit adjusts the k1 to a numerical value within a first range during a first period, and adjusts the k1 to a numerical value within a second range during a second period. The upper limit of the numerical value within the second range is smaller than a lower limit of the numerical value within the first range.

### CROSS-REFERENCE TO RELATED APPLICATIONS

This application is based upon and claims the benefit of priority from Japanese Patent Application No. 2022-146348, filed Sep. 14, 2022, the entire contents of which are incorporated herein by reference.

### FIELD

Embodiments described herein relate generally to a magnetic disk device and a refresh processing method.

### BACKGROUND

Magnetic disk devices such as a Conventional Magnetic Recording (CMR) (or conventional recording) magnetic disk device that writes data to a plurality of tracks at intervals in the radial direction of the disk, a Shingled write Magnetic Recording (SMR) or Shingled Write Recording (SWR) magnetic disk device that overwrites data to a plurality of tracks in the radial direction of the disk, and a hybrid recording type magnetic disk device that selectively performs the conventional magnetic recording and the shingled write magnetic recording, are known.

### BRIEF DESCRIPTION OF THE DRAWINGS

FIG. 1 is an exploded perspective view showing a magnetic disk device according to one of the embodiments.

FIG. 2 is an exploded perspective view showing a back surface side of a base and a control circuit board in the magnetic disk device.

FIG. 3 is a block diagram showing a configuration of the magnetic disk device.

FIG. 4 is a perspective view showing parts of the magnetic disk device, illustrating a plurality of disks and a plurality of heads.

FIG. 5 is a schematic view showing parts of a plurality of tracks where the conventional magnetic recording is performed.

FIG. 6 is a graph showing the variation of the absolute humidity of the environment to the environmental temperature of the magnetic disk device.

FIG. 7 is a graph showing the variation of the humidity inside the magnetic disk device to the initial use time of the magnetic disk device.

FIG. 8 is a graph showing the variation of the reducing amount of head flight to the humidity inside the magnetic disk device.

FIG. 9 is a schematic diagram showing three radially aligned sectors of the magnetic disk device to illustrate the ATI effect when the head flight amount is normal.

FIG. 10 is a schematic diagram showing three radially aligned sectors of the magnetic disk device to illustrate the ATI effect when the head flight amount is lower than normal.

FIG. 11 is a table showing the correspondence between the weight coefficients and the elapsed time from the timing when the power of a control unit of the magnetic disk device is first turned on.

FIG. 12 is a schematic diagram showing an example of the arrangement of a plurality of zones of a disk in the magnetic disk device according to a first modified example.

FIG. 13 is a schematic diagram showing three radially aligned sectors of the magnetic disk device according to a fourth modified example, illustrating an opposite side of the three sectors shown in FIG. 10.

### DETAILED DESCRIPTION

In general, according to one embodiment, there is provided a magnetic disk device including: a disk including a first target track which includes a first target sector and a first adjacent track which includes a first adjacent sector adjacent to the first target sector in a radial direction, in a first recording layer; a first head writing data to the first recording layer of the disk and reading data from the first recording layer; and a control unit. The control unit comprises: an adjustment unit capable of adjusting k1 that is a first weighting coefficient; a counter counting a first write count as the k1 times, when first write of data to the first adjacent sector is performed; a determination unit determining whether a first cumulative total of the first write count counted by the counter exceeds a first write count threshold value; and a refresh processing unit reading first target data in the first target sector, rewriting the first target data to the first target sector, to refresh the first target sector, and resetting the first write count counted by the counter, when the first cumulative total exceeds the first write count threshold value. The adjustment unit adjusts the k1 to a numerical value within a first range during a first period which is a specific period after timing of first turning on power of the control unit, and adjusts the k1 to a numerical value within a second range during a second period after the first period has elapsed. An upper limit of the numerical value within the second range is smaller than a lower limit of the numerical value within the first range.

According to another embodiment, there is provided a refresh processing method which is applied to the magnetic disk device comprising a disk including a first target track which includes a first target sector and a first adjacent track which includes a first adjacent sector adjacent to the first target sector in a radial direction, in a first recording layer, a first head writing data to the first recording layer of the disk and reading data from the first recording layer, and a control unit. The method comprises: when a first weighting coefficient is set to k1, counting a first write count as the k1 times, when first write of data to the first adjacent sector is performed; determining whether the first cumulative total of the first write count exceeds the first write count threshold value; when the first cumulative total exceeds the first write count threshold value, under control of the control unit, reading first target data in the first target sector, rewriting the first target data to the first target sector, to refresh the first target sector, and resetting the first write count; and when determining whether the first cumulative total exceeds the first write count threshold value, adjusting the k1 to a numerical value within a first range during a first period which is a specific period after timing of first turning on power of the control unit, and adjusting the k1 to a numerical value within a second range during a second period after the first period has elapsed. An upper limit of the numerical value within the second range is smaller than a lower limit of the numerical value within the first range.

One of the embodiments and each modified example will be described hereinafter with reference to the accompanying drawings.

### Embodiment

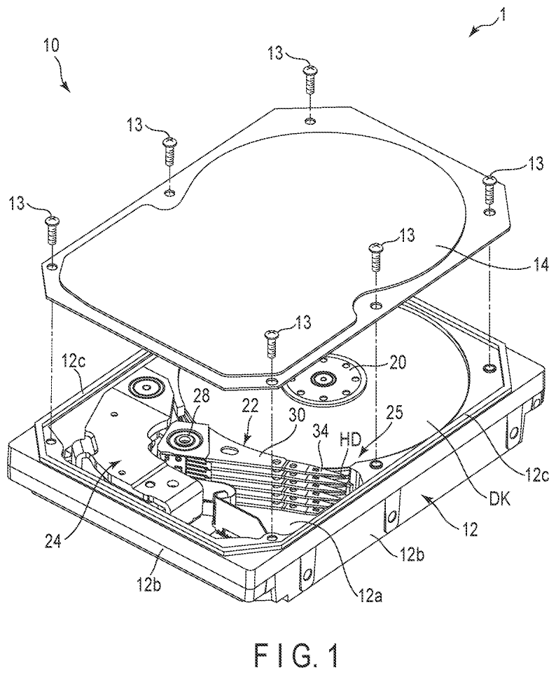

First, a magnetic disk device 1 and a refresh processing method according to one embodiment will be described in detail. First, a configuration of the magnetic disk device 1 will be described. FIG. 1 is an exploded perspective view showing the magnetic disk device 1 according to the embodiment. In the embodiment, the magnetic disk device 1 is a Conventional Magnetic Recording magnetic disk device.

As shown in FIG. 1, the magnetic disk device 1 comprises a housing 10 in a substantially rectangular shape. The housing 10 comprises a base 12 having a rectangular box shape whose upper surface is opened, and a top cover 14 that is fixed to the base 12 by a plurality of screws 13 to close the upper end opening of the base 12.

The base 12 comprises a rectangular bottom wall 12a opposed to and spaced apart from the top cover 14, and a sidewall 12b standing along a periphery of the bottom wall 12a, which are integrally molded of aluminum. The sidewall 12b includes a pair of long side walls that are opposed to each other and a pair of short side walls that are opposed to each other. A fixed rib 12c shaped in a substantially rectangular frame is provided to protrude on an upper end surface of the sidewall 12b.

The top cover 14 is formed of, for example, stainless steel in the shape of a rectangular plate. The top cover 14 is not welded to the base 12. Air is present inside the housing 10.

A plurality of, for example, one to six disks (magnetic disks) DK serving as recording media, and a spindle motor (SPM) 20 serving as a drive motor that supports and rotates the plurality of disks DK, are provided inside the housing 10. Each disk DK is formed to have a diameter of, for example, 95 mm (3.5 inches) and has recording layers (magnetic recording layers) on both sides.

In the embodiment, one to six disks DK are accommodated in the housing 10, but the number of disks DK is not limited to this. In addition, a single disk DK may be accommodated in the housing 10.

A plurality of heads (magnetic heads) HD that record and reproduce information on the disks DK, and a head stack assembly (actuator) 22 that movably supports these heads HD with respect to the disks DK are accommodated in the housing 10. In addition, a voice coil motor (hereinafter referred to as VCM) 24, a ramp load mechanism 25, and the like are accommodated in the housing 10.

The head stack assembly 22 comprises a rotatable bearing unit 28, a plurality of arms 30 extending from the bearing unit 28, and suspensions 34 extending from the respective arms 30. A head HD is supported at a tip portion of each suspension 34.

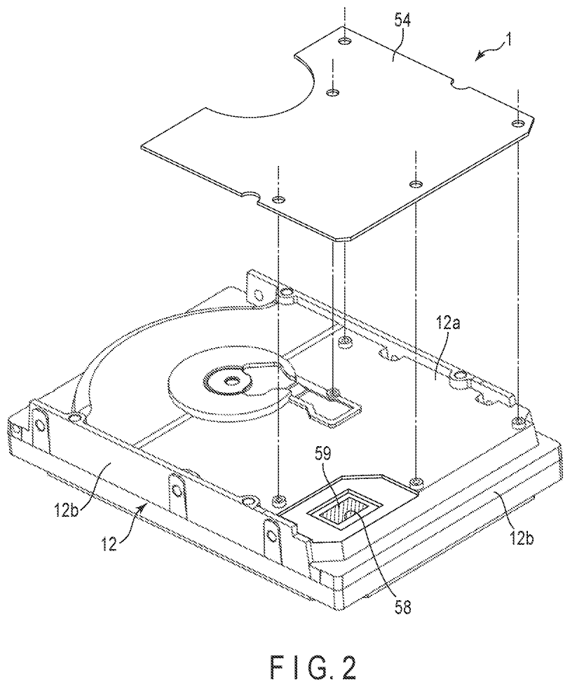

FIG. 2 is an exploded perspective view showing the back surface side of the base and the control circuit board in the magnetic disk device 1.

As shown in FIG. 2, a control circuit board 54 is located outside the housing 10 and is mounted on the housing 10. The control circuit board 54 is fixed to the outer surface of the bottom wall 12a of the base 12 by screws.

In the bottom wall 12a of the base 12, for example, a rectangular first through hole 58 is formed at an end portion on one short side. The first through hole 58 is closed by a ring-shaped sealing member (connector packing) and a plate-shaped lid 59. The lid 59 and the bottom wall 12a sandwich the above-mentioned sealing member which surrounds the first through hole 58. The sealing member is formed of an elastic material such as resin, and examples of the resin are rubber, elastomer, and the like.

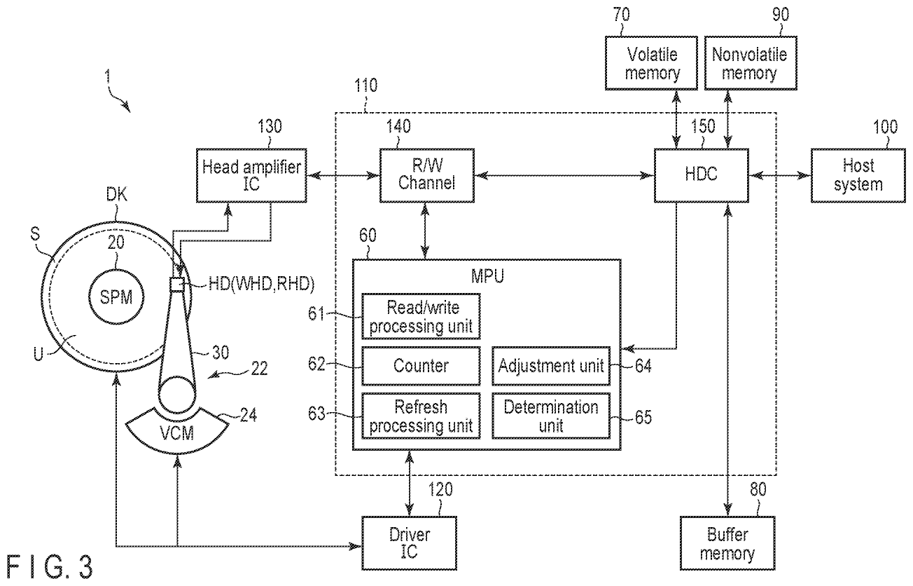

FIG. 3 is a block diagram showing the configuration of the magnetic disk device 1 according to the embodiment.

As shown in FIG. 3, the magnetic disk device 1 comprises a head stack assembly 22, a driver IC 120, a head amplifier integrated circuit (hereinafter referred to as a head amplifier IC or preamplifier) 130, a volatile memory 70, a buffer memory (buffer) 80, a nonvolatile memory 90, and a system controller 110 that is a single-chip integrated circuit. In addition, the magnetic disk device 1 is connected to a host system (hereinafter simply referred to as a host) 100.

The head stack assembly 22 controls the movement of the head HD mounted on the arm 30 to a target position on the disk DK by driving the VCM 24.

A user data area U that can be used for the user, and a system area S where information necessary for the system management is written are assigned to the area of the disk DK where the data can be written. Any track among a plurality of tracks on the disk DK is referred to as a target track, and a track adjacent to the target track in the radial direction of the disk DK is referred to as an adjacent track. In the target track, any sector among a plurality of sectors aligned in the circumferential direction of the disk DK is referred to as a target sector. In the adjacent track, a sector adjacent to the target sector in the radial direction of the disk DK among the plurality of sectors aligned in the circumferential direction of the disk DK is referred to as an adjacent sector.

The head HD comprises a slider as a main body, and comprises a write head WHD and a read head RHD mounted on the slider. The write head WHD writes the data to the disk DK. The read head RHD reads the data recorded on data tracks of the disk DK.

The driver IC 120 controls driving the SPM 20 and the VCM 24 under control of the system controller 110 (more specifically, MPU 60 to be described later).

The head amplifier IC 130 comprises a read amplifier and a write driver. The read amplifier amplifies a read signal read from the disk DK and outputs the amplified read signal to the system controller 110 (more specifically, a read/write (R/W) channel 140 to be described later). The write driver outputs a write current corresponding to a signal output from the R/W channel 140 to the head HD.

The volatile memory 70 is a semiconductor memory where the stored data is lost when power supply is cut off. The volatile memory 70 stores data and the like necessary for processing in each of the units of the magnetic disk device 1. The volatile memory 70 is, for example, a dynamic random access memory (DRAM) or a synchronous dynamic random access memory (SDRAM).

The buffer memory 80 is a semiconductor memory which temporarily records data and the like transmitted and received between the magnetic disk device 1 and the host 100. The buffer memory 80 may be formed integrally with the volatile memory 70. The buffer memory 80 is, for example, a DRAM, a static random access memory (SRAM), an SDRAM, a ferroelectric random access memory (FeRAM), a magnetoresistive random access memory (MR-AM) or the like.

The nonvolatile memory 90 is a semiconductor memory which records the data stored even when power supply is cut off. The nonvolatile memory 90 is, for example, a NOR type or NAND type flash read only memory (flash ROM: FROM).

The system controller (controller) 110 is realized by, for example, using a large scale integrated circuit (LSI) referred to as a system-on-a-chip (SoC) in which a plurality of elements are integrated on a single chip. The system controller 110 includes a read/write (R/W) channel 140, a hard disk controller (HDC) 150, and a microprocessor (MPU) 60. The system controller 110 is electrically connected to the driver IC 120, the head amplifier IC 130, the volatile memory 70, the buffer memory 80, the nonvolatile memory 90, and the host 100.

The R/W channel 140 executes signal processing of read data transferred from the disk DK to the host 100 and write data transferred from the host 100 in accordance with instructions from the MPU 60 to be described later. The R/W channel 140 comprises a circuit or function of modulating the write data. In addition, the R/W channel 140 comprises a circuit or a function of measuring the signal quality of the read data. The R/W channel 140 is electrically connected to, for example, the head amplifier IC 130, the HDC 150, the MPU 60 and the like.

The HDC 150 controls data transfer between the host 100 and the R/W channel 140 in response to an instruction from the MPU 60 to be described later. The HDC 150 is electrically connected to, for example, the R/W channel 140, the MPU 60, the volatile memory 70, the buffer memory 80, the nonvolatile memory 90, and the like.

The MPU 60 is a control unit or main controller which controls each of units of the magnetic disk device 1. The MPU 60 controls the VCM 24 via the driver IC 120 to execute servo control for positioning the head HD. The MPU 60 controls the operation of writing the data to the disk DK and selects a storage destination of the write data transferred from the host 100. In addition, the MPU 60 controls the operation of reading the data from the disk DK and controls the processing of the read data transferred from the disk DK to the host 100. The MPU 60 is connected to each of the units of the magnetic disk device 1. The MPU 60 is electrically connected to, for example, the driver IC 120, the R/W channel 140, the HDC 150 and the like.

The MPU 60 comprises a read/write processing unit 61, a counter 62, a refresh processing unit 63, an adjustment unit 64, and a determination unit 65. The MPU 60 executes processing of each of these units, for example, the read/write processing unit 61, the counter 62, the refresh processing unit 63, the adjustment unit 64, the determination unit 65 and the like, on firmware. The MPU 60 may comprise each of these units as a circuit.

The read/write processing unit 61 controls the read processing and the write processing of the data according to a command from the host 100. The read/write processing unit 61 controls the VCM 24 via the driver IC 120, positions the head HD at a target position (predetermined radial position) on the disk DK, and executes the read processing or the write processing.

The adjustment unit 64 can adjust weight coefficients k (k1, k2, and k3).

The counter 62 can count the number of writes (also referred to as a write count) N as k times every time the data is written for each sector of the disk DK. The counter 62 can count the number of writes N as k times, when the data is written for each sector of the disk DK. For example, the counter 62 can store the write count N in the nonvolatile memory 90 and manage the write count N by the nonvolatile memory 90. The recording unit where the counter 62 stores the write count N is not limited to the nonvolatile memory 90, but may be any recording unit in the magnetic disk device 1, for example, the system area S.

The determination unit 65 has a write count threshold value. The determination unit 65 can determine whether the cumulative total of the write count N exceeds the write count threshold value. For example, the determination unit 65 determines whether the cumulative total of the write count N exceeds the write count threshold value in the above-described adjacent sector.

The refresh processing unit 63 can control the read processing and write processing of the data in accordance with the determination result of the determination unit 65. For example, when the determination unit 65 determines that the cumulative total of the write count N in the adjacent sector exceeds the write count threshold value, the determination unit 65 outputs a signal to execute refresh processing (also referred to as a refresh signal) to the refresh processing unit 63, and the refresh processing unit 63 reads the target data of the above-described target sector, rewrites the target data to the target sector, to refresh the target sector, and resets the write count N in the target sector. For example, the refresh processing unit 63 resets the write count N stored in the nonvolatile memory 90 to 0.

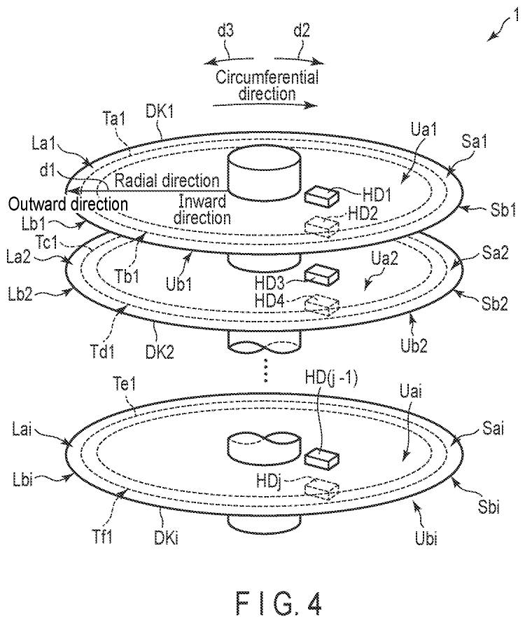

FIG. 4 is a perspective view showing parts of the magnetic disk device 1, illustrating a plurality of disks DK and a plurality of heads HD.

As shown in FIG. 4, the rotation of direction of the disks DK in the circumferential direction is referred to as a rotational direction d3. In the example shown in FIG. 4, the rotational direction is a counterclockwise direction, but may be an opposite direction (clockwise). In addition, a direction d2 of travel of the heads HD relative to the disks DK is opposite to the rotational direction d3.

The magnetic disk device 1 comprises i disks, from disk DK1 through disk DKi, and j heads, from head HD1 through head HDj. In the embodiment, the number of heads HD is twice the number of disks DK (j=2×i).

The disks DK1 through DKi are provided coaxially to overlap with from each other at intervals. The diameters of the disks DK1 to DKi are the same as each other. The terms “same”, “identical”, “matching”, “equivalent” and the like imply not only the meaning of being exactly the same, but also the meaning of being different to the extent that they can be regarded as substantially the same. The diameters of the disks DK1 through DKi may be different from each other.

Each disk DK has recording layers L on both sides. For example, the disk DK1 has a first recording layer La1 and a second recording layer Lb1 on the side opposite to the first recording layer La1. The disk DK2 has a first recording layer La2 and a second recording layer Lb2 on the side opposite to the first recording layer La2. The disk DKi has a first recording layer Lai and a second recording layer Lbi on the side opposite to the first recording layer Lai. Each first recording layer La may be referred to as a front surface or a recording surface. Each second recording layer Lb may be referred to as a back surface or recording surface.

As described above, the magnetic disk device 1 of the embodiment is a Conventional Magnetic Recording magnetic disk device. For this reason, the user data area U of each recording layer L is a conventional magnetic recording area. In the Conventional Magnetic Recording magnetic disk device, writing the data randomly in the user data area U is permitted, i.e., conventional magnetic recording is permitted.

Each recording layer L includes a user data area U and a system area S. The first recording layer La1 includes a user data area Ua1 and a system area Sa1. The second recording layer Lb1 includes a user data area Ub1 and a system area Sb1. The first recording layer La2 includes a user data area Ua2 and a system area Sa2. The second recording layer Lb2 includes a user data area Ub2 and a system area Sb2. The first recording layer Lai includes a user data area Uai and a system area Sai. The second recording layer Lbi includes a user data area Ubi and a system area Sbi.

A track sandwiched between double dashed lines in the figure, of the user data area Ua1 (first recording layer La1), is referred to as track Ta1. A track located on a side opposite to the track Ta1, of the user data area Ub1 (second recording layer Lb1), is referred to as track Tb1.

A track sandwiched between double dashed lines in the figure, of the user data area Ua2 (first recording layer La2), is referred to as track Tc1. A track located on a side opposite to the track Tc1, of the user data area Ub2 (second recording layer Lb2), is referred to as track Td1.

A track sandwiched between double dashed lines in the figure, of the user data area Uai (first recording layer Lai), is referred to as track Te1. A track located on a side opposite to the track Te1, of the user data area Ubi (second recording layer Lbi), is referred to as track Tf1.

In the embodiment, the tracks Ta1, Tb1, Tc1, Td1, Te1, and Tf1 are located on the same cylinder.

The heads HD are opposed to the disks DK. In the embodiment, one head HD is opposed to each recording layer L of the disk DK. For example, the head HD1 is opposed to the first recording layer La1 of the disk DK1, writes the data to the first recording layer La1, and reads the data from the first recording layer La1. The head HD2 is opposed to the second recording layer Lb1 of the disk DK1, writes the data to the second recording layer Lb1, and reads the data from the second recording layer Lb1. The head HD3 is opposed to the first recording layer La2 of the disk DK2, writes the data to the first recording layer La2, and reads the data from the first recording layer La2. The head HD4 is opposed to the second recording layer Lb2 of the disk DK2, writes the data to the second recording layer Lb2, and reads the data from the second recording layer Lb2. The head HDj−1 is opposed to the first recording layer Lai of the disk DKi, writes the data to the first recording layer Lai, and reads the data from the first recording layer Lai. The head HDj is opposed to the second recording layer Lbi of the disk DKi, writes the data to the second recording layer Lbi, and reads the data from the second recording layer Lbi.

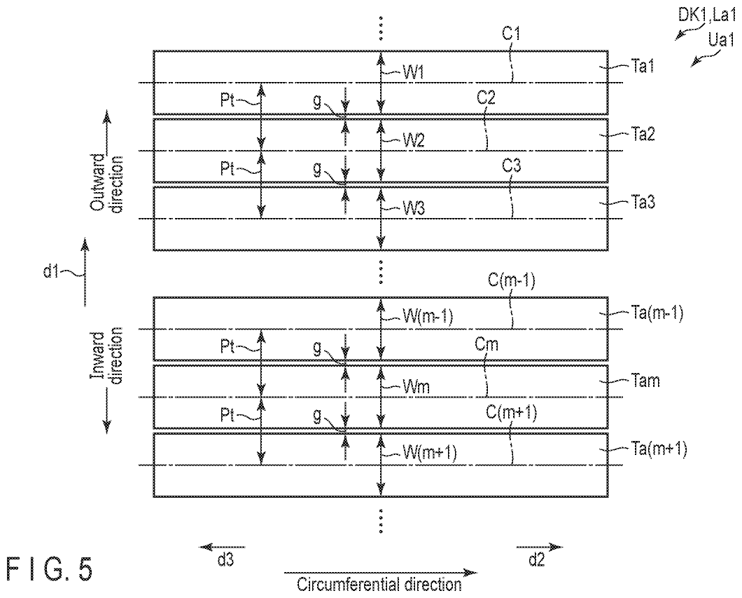

FIG. 5 is a schematic view showing parts of a plurality of tracks where the conventional magnetic recording is performed.

As shown in FIG. 5, the first recording layer La1 of the disk DK1 includes tracks Ta1, Ta2, Ta3, . . . , Ta(m−1), Tam, Ta(m+1), and the like arranged in the radial direction d1. In the figure, the track Ta1 is located on the outermost circumference OD side of the disk DK1, and the track Ta(m+1) is located on the innermost circumference ID side of the disk DK1.

The track Ta1 has a track width W1 in the radial direction d1 and a track center C1 in the center of the radial direction d1. Similarly to the track Ta1, the track Ta2 has a track width W2 and a track center C2, the track Ta3 has a track width W3 and a track center C3, the track Ta(m−1) has a track width W(m−1) and a track center C(m−1), the track Tam has a track width Wm and a track center Cm, and the track Ta(m+1) has a track width W(m+1) and a track center C(m+1). The track widths W1 through W(m+1) are the same as each other. However, the track widths W1 through W(m+1) may be different from each other.

The tracks Ta1 through Ta(m+1) are arranged at a pitch (conventional recording track pitch) Pt in the radial direction d1. For example, the track center C1 is separated from the track center C2 by the pitch Pt in the radial direction d1, and the track center C2 is separated from the track center C3 by the pitch Pt in the radial direction d1. In addition, the track center C(m−1) is separated from the track center Cm by the pitch Pt in the radial direction d1, and the track center Cm is separated from the track center C(m+1) by the pitch Pt in the radial direction d1. The tracks Ta1 through Ta(m+1) may be arranged at different pitches in the radial direction d1, respectively.

In the Conventional Magnetic Recording magnetic disk device, high density can be achieved by designing a narrower pitch Pt to increase the storage capacity.

In addition, in the example shown in FIG. 5, the tracks Ta1 through Ta(m+1) are located with a gap g in the radial direction d1. For example, the track Ta1 is separated from the track Ta2 by the gap g in the radial direction d1, and the track Ta2 is separated from the track Ta3 by the gap g in the radial direction d1. Moreover, the track Ta(m−1) is separated from the track Tam by the gap g in the radial direction d1, and the track Tam is separated from the track Ta(m+1) by the gap g in the radial direction d1. The tracks Ta1 through Ta(m+1) may be arranged at different gaps from each other.

In FIG. 5, each track Ta has a rectangular shape for convenience of description but, in reality, each track Ta is curved along the circumferential direction. In addition, each track may have a wave shape extending in the circumferential direction while varying in the radial direction d1.

When performing the write processing, the read/write processing unit 61 (or the refresh processing unit 63) positions the head HD1 at the track center C1 and writes the data to the track Ta1, positions the head HD1 at the track center C2 and writes the data to the track Ta2, positions the head HD1 at the track center C3 and writes the data to the track Ta3, positions the head HD1 at the track center C(m−1) and writes the data to the track Ta(m−1), positions the head HD1 at the track center Cm and writes the data to the track Tam, positions the head HD1 at the track center C(m+1) and writes the data to the track Ta(m+1).

In the example shown in FIG. 5, the read/write processing unit 61 may perform the write processing sequentially to the tracks Ta1 through Ta(m+1) or may perform the write processing randomly to a predetermined sector of each of the tracks Ta1 through Ta(m+1).

The magnetic disk device 1 of the embodiment is configured as described above.

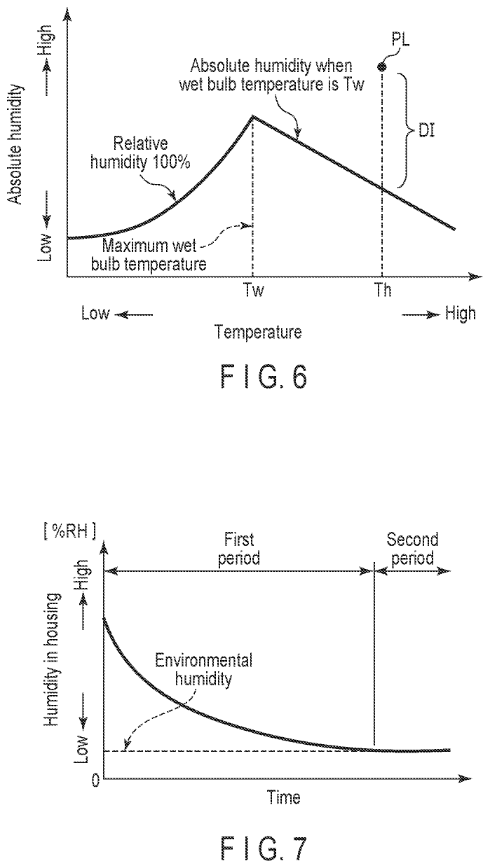

Next, influence of adjacent track interference (ATI) will be described with reference to FIG. 6 to FIG. 10. FIG. 6 is a graph showing the variation in the absolute humidity of the environment to the environmental temperature of the magnetic disk device 1.

As shown in FIG. 6, the environmental humidity is defined by the maximum wet bulb temperature, and the absolute humidity is lower as the temperature becomes higher than the maximum wet bulb temperature Tw as understood from a straight line in the graph. When the relative humidity is 100% below the temperature Tw, the absolute humidity is higher as the temperature becomes higher as understood from a curve in the graph. The absolute humidity of the environment is the value shown in the graph. For example, if the relative humidity is not 100%, but 80%, the absolute humidity of the environment is the value less than or equal to that in the graph.

The above environment means the outside of the magnetic disk device 1, the surroundings of the magnetic disk device 1, or the like. The above-described environmental temperature is the temperature of the atmosphere outside the magnetic disk device 1. The above-described environmental humidity is the humidity of the atmosphere outside the magnetic disk device 1.

By the way, in some cases, the magnetic disk device 1 is left for a while in an environment (storage environment) with the above-described temperature Tw and high humidity, and then the magnetic disk device 1 is used at an environmental temperature Th higher than the above-described temperature Tw.

The humidity (absolute humidity) inside the magnetic disk device 1 in a case where the environmental temperature is raised to temperature Th is plotted as point PL. As understood from the point PL and the graph, a difference DI between the absolute humidity inside the magnetic disk device 1 and the absolute humidity of the environment becomes larger. It is thought that the humidity inside the magnetic disk device 1 is extremely high due to moisture absorbed by the components (for example, activated carbon) inside the magnetic disk device 1.

FIG. 7 is a graph showing the variation in humidity inside the magnetic disk device 1 to the initial use time of the magnetic disk device 1.

As shown in FIG. 7, the humidity inside the magnetic disk device 1 escapes to the outside of the magnetic disk device 1, but not in a timely manner. The humidity inside the magnetic disk device 1 decreases as the use time elapses, and the humidity inside the magnetic disk device 1 approaches the environmental humidity as the use times elapses. It can be understood that the humidity inside the magnetic disk device 1 deviates from the environmental humidity only for a certain period of time after the magnetic disk device 1 is moved from the storage environment to the use environment.

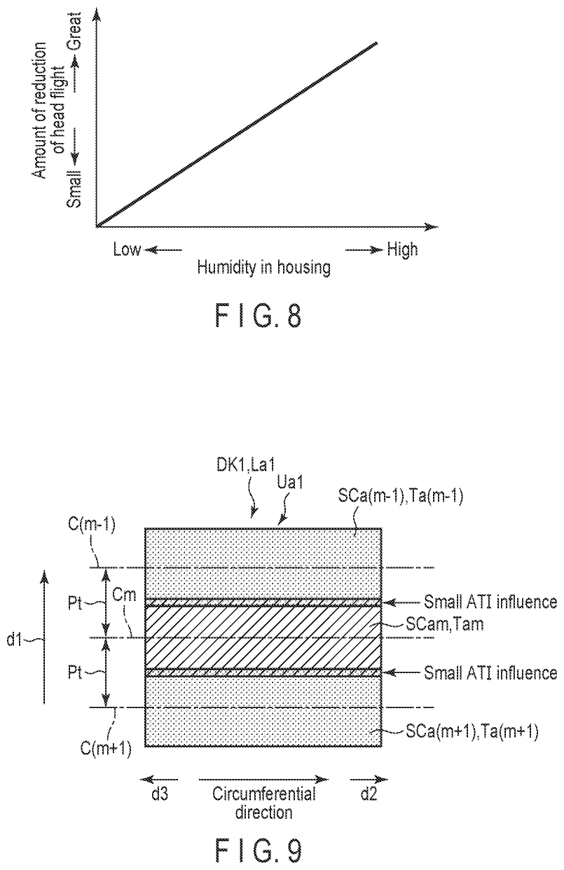

FIG. 8 is a graph showing the variation in the amount of reduction of the head HD flight to the humidity inside the magnetic disk device 1. In FIG. 8, the temperature inside the magnetic disk device 1 is set to be constant.

As shown in FIG. 8, the magnetic disk device 1 generally has the characteristic that the amount of reduction of the head HD flight increases when the internal humidity is high. When the humidity is high, the head HD does not fly sufficiently.

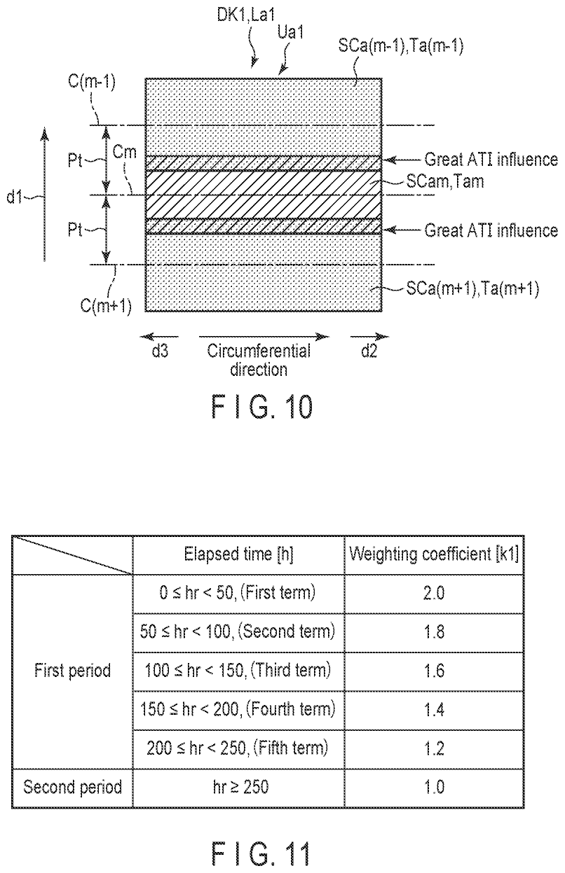

FIG. 9 is a schematic diagram showing three sectors SCa(m−1), SCam, and SCa(m+1) arranged in the radial direction d1 of the magnetic disk device 1, illustrating the ATI influence in a case where the amount of flight of the head HD1 is normal. FIG. 10 is a schematic diagram showing the three sectors SCa(m−1), SCam, and SCa(m+1), illustrating the ATI influence in a case where the amount of flight of the head HD1 is smaller than the normal amount.

In FIG. 9 and FIG. 10, hatch lines are drawn in the area where the write processing of the data for the sector SCam is performed, and a dot pattern is drawn in the area where the data write processing for the sector SCa(m−1) is performed and the area where the data write processing for the sector SCa(m+1) is performed.

As shown in FIG. 9 and FIG. 10, the track Tam includes sector SCam. The track Ta(m−1) includes the sector SCa(m−1) adjacent to the sector SCam in the radial direction d1. The track Ta(m+1) includes the sector SCa(m+1) adjacent to the sector SCam in the radial direction d1.

In the following descriptions, the track Tam is referred to as a first target track Tam, the track Ta(m−1) is referred to as a first adjacent track Ta(m−1), and the track Ta(m+1) is referred to as a first adjacent track Ta(m+1). The first adjacent track Ta(m+1) is a first inner adjacent track located inside the first target track Tam. The first adjacent track Ta(m−1) is a first outer adjacent track located outside the first target track Tam.

In addition, the sector SCam is referred to as a first target sector SCam, the sector SCa(m−1) is referred to as a first adjacent sector SCa(m−1), and the sector SCa(m+1) is referred to as a first adjacent sector SCa(m+1). The first adjacent sector SCa(m+1) is a first inner adjacent sector adjacent to the first target sector SCam in the radial direction d1. The first adjacent sector SCa(m−1) is a first outer adjacent sector adjacent to the first target sector SCam in the radial direction d1.

As shown in FIG. 9, when the amount of flight of the head HD1 normal, the data write processing for the first adjacent sector SCa(m−1) is performed or the data write processing for the first adjacent sector SCa(m+1) is performed, but the ATI influence to the data of the first target sector SCam is small.

As shown in FIG. 10, however, when the amount of flight of the head HD1 is smaller than a normal amount, the writing characteristics to the disk DK1 increases. Since the magnetic influence from the head HD1 to the disk DK1 becomes strong, the ATI influence to the data in the first target sector SCam or its neighboring area becomes large when the data write processing to the first adjacent sector SCa(m−1) is performed or the data write processing to the first adjacent sector SCa(m+1) is performed.

Furthermore, when writing the data to the first adjacent sectors SCa(m−1) and SCa(m+1) is performed many times, data is also written (overwritten) to the vicinity of the boundary of the first adjacent sectors SCa(m−1) and SCa(m+1) in the first target sector SCam every time writing is performed. If the number of writing to the first adjacent sectors SCa(m−1) and SCa(m+1) increases, the original target data in the first target sector SCam may not be able to be read.

Based on the above, the magnetic disk device 1 performs refresh processing referred to as an ATI refresh operation when the number of writes to the first adjacent sectors SCa(m−1) and SCa(m+1) exceeds the write count threshold value in consideration of the ATI influence. The refresh processing is the processing of reading the data in the first target sector SCam, and rewriting the read data to the first target sector SCam, to refresh the first target sector SCam. The situation that the original target data in the first target sector SCam cannot be read due to the ATI influence can be thereby avoided in advance.

By the way, there is a problem with the above-described refresh processing. For example, when the humidity inside the magnetic disk device 1 (housing 10) is extremely high, the ATI refresh cannot be performed in time, and the risk of an error occurring when reading the data in the first target sector SCam may increase. To ensure that the ATI refresh can be performed in time, the above write count threshold value needs to be lowered even when the humidity inside the magnetic disk device 1 is extremely high.

However, if the write count threshold value is lowered, deterioration of the performance of the magnetic disk device 1 may be considered and the magnetic disk device 1 will not be able to efficiently rewrite the data over a long period of time. Therefore, the embodiment solves the above-described problem and provides a magnetic disk device 1 and a refresh processing method that can efficiently rewrite the data. The embodiment performs, for example, the ATI refresh processing by changing conditions for the first and second periods shown in FIG. 7. More specifically, in order to minimize the deterioration of the performance of the magnetic disk device 1 as much as possible, the magnetic disk device 1 comprises a function of accelerating the timing of the ATI refresh during the first period (a certain period after the start of use).

Next, the refresh processing method of the embodiment will be described together with the operation of the magnetic disk device 1. Application of the refresh processing to the first target sector SCam of the first recording layer La1 of the disk DK1 will be described (FIG. 10). The adjustment unit 64 can adjust k1 that is a first weighting coefficient (FIG. 3).

As shown in FIG. 3, FIG. 4, and FIG. 10, when the refresh processing method is started, the counter 62 first counts the first write count N1 as k1 times, when first write of the data to the first adjacent sectors SCa(m−1) and SCa(m+1) is performed.

Next, the determination unit 65 determines whether the first cumulative total of the first write count N1 exceeds the first write count threshold value.

When the determination unit 65 determines that the first cumulative total has exceeded the first write count threshold value, under the control of MPU 60, the refresh processing unit 63 reads the first target data in the first target sector SCam, rewrites the first target data to the first target sector SCam, to refresh the first target sector SCam, and resets the first write count N1.

When determining whether the first cumulative total exceeds the first write count threshold value, the adjustment unit 64 adjusts the first weighting coefficient k1 to a numerical value within the first range during the first period that is a specific period of time from the timing when the power of the MPU 60 is first turned on. For example, the timing of changing from the first period to the second period is the timing when the humidity inside the magnetic disk unit 1 becomes substantially the same as the environmental humidity. The adjustment unit 64 adjusts the first weighting coefficient k1 to a numerical value within the second range during the second period after the first period has elapsed. The upper limit of the numerical value within the second range is smaller than the lower limit of the numerical value within the first range.

In the embodiment, the adjustment unit 64 adjusts the first weighting coefficient k1 to a numerical value greater than 1 during the first period and fixes the first weighting coefficient k1 to 1 during the second period. The numerical value within the first range is a numerical value exceeding 1, and the numerical value within the second range is a numerical value smaller than or equal to 1. However, the adjustment unit 64 may adjust the weighting coefficient k such as the first weighting coefficient k1 a plurality of times during the second period or may fix the weighting coefficient k to a numerical value other than 1. Alternatively, the adjustment unit 64 may use the weighting coefficient k such as the first weighting coefficient k1 during the first period and use a different weighting coefficient during the second period.

Thus, the first cumulative total can exceed the first write count threshold value in the first period more easily than in the second period. The deterioration of the performance caused by the operation of the ATI refresh can be minimized during the second period while avoiding read errors of the data in the first target sector SCam due to the ATI influence during the first period.

The timing for resetting the first write count N1 is not limited to the timing for the ATI refresh of the first target sector SCam. For example, when the data is written to the first target sector SCam before the first cumulative total exceeds the first write count threshold value, the refresh processing unit 63 resets the first write count N1 counted by the counter 62.

In addition, the first weighting coefficient k1 may be varied according to the length of the period during which the magnetic disk device 1 is used. FIG. 11 is a table showing an example of the correspondence between the time elapsed from the timing when the power of the MPU 60 of the magnetic disk device 1 is first turned on and the first weight coefficient k1.

As shown in FIG. 3 and FIG. 11, if the magnetic disk device 1 stores the table shown in FIG. 11 as parameters, the adjustment unit 64 can adjust the first weighting coefficient k1 by referring to the above table.

The adjustment unit 64 can adjust the first weighting coefficient k1 to k1a during a first term of the first period (k1a=2.0). The adjustment unit 64 can adjust the first weighting coefficient k1 to k1b during a second term following the first term of the first period (k1b=1.8). The adjustment unit 64 can adjust the first weighting coefficient k1 to k1c during a third term following the second term of the first period (k1c=1.6). The adjustment unit 64 can adjust the first weighting coefficient k1 to kid during a fourth term following the third term of the first period (k1d=1.4). The adjustment unit 64 can adjust the first weighting coefficient k1 to k1e during a fifth term following the fourth term of the first period (k1e=1.2). The adjustment unit 64 can adjust the first weighting coefficient k1 to k1x during the second period (k1x=1.0). In the embodiment, k1a>k1b>k1c>k1d>k1e>k1x.

For example, when the first write of the data to the first adjacent sectors SCa(m−1) and SCa(m+1) is performed during the second period, the first write count N1 is counted as 1.0 time. When the first write of the data to the first adjacent sectors SCa(m−1) and SCa(m+1) is performed in the first term, the first write count N1 is counted as 2.0 times. When the first write of the data to the first adjacent sectors SCa(m−1) and SCa(m+1) is performed in the second term, the first write count N1 is counted as 1.8 times. The first write count threshold value is a value having a margin to the unrecovered limit BER (bit error rate) and is, for example, 10,000 times. The first write count threshold value and the first weighting coefficient k1 are designed in consideration of various variations including the use environment of the magnetic disk device 1 and individual differences of the magnetic disk device 1.

Since the humidity inside the magnetic disk device 1 gradually approaches the environmental humidity and the amount of flight of the head HD1 gradually approaches the normal amount of flight as the use of the magnetic disk device 1 continues, the adjustment unit 64 may lower the first weighting coefficient k1 in stages. The magnetic disk device 1 can thereby rewrite the data even more efficiently.

According to the magnetic disk device 1 and the refresh processing method of the embodiment configured as described above, the adjustment unit 64 can adjust the first weighting coefficient k1 to a numerical value within the first range during the first period which is a specific period after the timing of first using the magnetic disk device 1. The adjustment unit 64 can adjust the first weighting coefficient k1 to a numerical value within the second range during the second period after the first period has elapsed.

The magnetic disk device 1 and the refresh processing method capable of efficiently rewriting the data as compared with the case where the first weighting coefficient k1 is always fixed to a specific numerical value (for example, “1”) can be obtained.

### First Modified Example

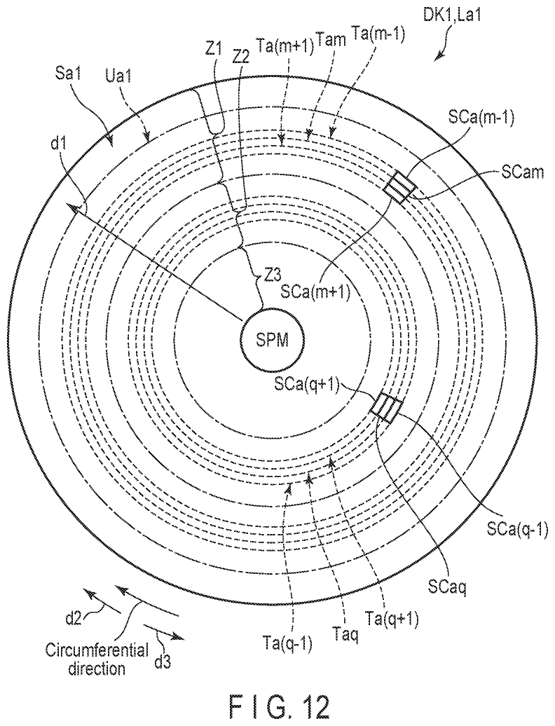

Next, a first modified example will be described. The magnetic disk device 1 is configured in the same manner as the above-described embodiment except for the configuration described in the first modified example. The refresh processing method is the same as that of the above-described embodiment except for the processing described in the first modified example. FIG. 12 is a schematic diagram showing an example of an arrangement of a plurality of zones Z of the disk DK1 of the magnetic disk device 1 according to the first modified example.

As shown in FIG. 12, the disk DK1 includes a first zone Z1, a second zone Z2 located inside the first zone Z1, and a third zone Z3 located inside the second zone Z2 in the first recording layer La1. The first zone Z1m is also referred to as zone 0, the second zone Z2 is also referred to as zone 1, and the third zone Z3 is also referred to as zone 2.

The first zone Z1 includes a plurality of tracks T such as the first target track Tam including the first target sector SCam, the first adjacent track Ta(m−1) including the first adjacent sector SCa(m−1), and the first adjacent track Ta(m+1) including the first adjacent sector SCa(m+1).

The second zone Z2 includes a plurality of tracks T such as a second target track Taq including a second target sector SCaq, a second adjacent track Ta(q−1) including a second adjacent sector SCa(q−1), and a second adjacent track Ta(q+1) including a second adjacent sector SCa(q+1).

The second adjacent track Ta(q+1) is a second inner adjacent track located inside the second target track Taq, and the second adjacent sector SCa(q+1) is the second inner adjacent sector adjacent to the second target sector SCaq in the radial direction d1. The second adjacent track Ta(q−1) is a second outer adjacent track located outside the second target track Taq, and the second adjacent sector SCa(q−1) is a second outer adjacent sector adjacent to the second target sector SCaq in the radial direction d1.

The disk DK1 of the first modified example is configured as described above.

Next, the refresh processing method of the first modified example will be described together with the operation of the magnetic disk device 1. Application of the refresh processing to the second target sector SCaq of the first recording layer La1 of the disk DK1 will be described. In the first modified example, the adjustment unit 64 applies the first weighting coefficient k1 to the first zone Z1, the second zone Z2, and the third zone Z3.

As shown in FIG. 3, FIG. 4, and FIG. 12, when the refresh processing method is started, the counter 62 counts the second write count N2 as k1 times, when second write of the data to the second adjacent sectors SCa(q−1) and SCa(q+1) is performed.

The determination unit 65 applies a second write count threshold value to the second zone Z2. The determination unit 65 applies the first write count threshold value to the first zone Z1. Next, the determination unit 65 determines whether a second cumulative total of the second write count N2 counted by the counter 62 exceeds the second write count threshold value.

When the determination unit 65 determines that the second cumulative total has exceeded the second write count threshold value, under control of the MPU 60, the refresh processing unit 63 reads the second target data in the second target sector SCaq, rewrites the second target data to the second target sector SCaq, to refresh the second target sector SCaq, and resets the second write count N2. When determining whether the second cumulative total exceeds the second write count threshold value, the adjustment unit 64 adjusts the first weighting coefficient k1 to a numerical value within the first range during the first period and adjusts the first weighting coefficient k1 to a numerical value within the second range during the second period (for example, fixes the numerical values to 1).

Based on the above, the first modified example can obtain the same advantages as those of the above-described embodiment.

Since the first weighting coefficient k1 is common in the first zone Z1, the second zone Z2, and the third zone Z3, the first weighting coefficient k1 is applied in the same manner when counting the first write count N1 and the second write count N2. However, the write count threshold value can be set for each zone Z. In the first modified example, the ATI refresh processing can be performed by changing the conditions for each zone Z. For this reason, the first write count threshold value and the second write count threshold value may be different from each other. For example, if the ATI influence in the first zone Z1 is greater than the ATI influence in the second zone Z2, the first write count threshold value may be set to be smaller than the second write count threshold value. The magnetic disk device 1 can thereby rewrite the data even more efficiently.

### Second Modified Example

Next, a second modified example will be described. The magnetic disk device 1 is configured in the same manner as the above-described first modified example except for the configuration described in the second modified example. The refresh processing method is the same as that of the above-described embodiment except for the processing described in the second modified example.

The refresh processing method of the second modified example will be described together with the operation of the magnetic disk device 1. Application of the refresh processing to the second target sector SCaq of the first recording layer La1 of the disk DK1 will be described. In the second modified example, the determination unit 65 applies the first write count threshold value to the first zone Z1, the second zone Z2, and the third zone Z3.

As shown in FIG. 3, FIG. 4, and FIG. 12, the adjustment unit 64 can adjust the weighting coefficient for each zone Z. For example, the adjustment unit 64 can adjust k2 that is a second weighting coefficient applied to the second zone Z2. When the refresh processing method is started, the adjustment unit 64 adjusts the second weighting coefficient k2 to a numerical value within the first range during the first period and adjusts the second weighting coefficient k2 to a numerical value within the second range during the second period.

When the second write of the data to the second adjacent sectors SCa(q−1) and SCa(q+1) is performed, the counter 62 counts the second write count N2 as k2 times.

The determination unit 65 applies the first write count threshold value to the first zone Z1, the second zone Z2, and the third zone Z3. Next, the determination unit 65 determines whether a second cumulative total of the second write count N2 counted by the counter 62 exceeds the first write count threshold value.

When the determination unit 65 determines that the second cumulative total has exceeded the first write count threshold value, under control of the MPU 60, the refresh processing unit 63 reads the second target data in the second target sector SCaq, rewrites the second target data to the second target sector SCaq, to refresh the second target sector SCaq, and resets the second write count N2.

Based on the above, the second modified example can obtain the same advantages as those of the above-described first modified example.

Since the first write count threshold value is common in the first zone Z1, the second zone Z2, and the third zone Z3, the first wright count threshold value is applied in the same manner when determining the first cumulative total and the second cumulative total. However, the weighting coefficient can be set for each zone Z. In the second modified example, too, the ATI refresh process can be performed by changing the conditions for each zone Z. For this reason, the first weighting coefficient k1 and the second weighting coefficient k2 may be different from each other. For example, if the ATI influence in the first zone Z1 is greater than the ATI influence in the second zone Z2, the first weighting coefficient k1 may be set to be greater than the second weighting coefficient k2. The magnetic disk device 1 can thereby rewrite the data even more efficiently.

### Third Modified Example

Next, a third modified example will be described. The magnetic disk device 1 is configured in the same manner as the above-described first and second modified examples except for the configuration described in the third modified example. The refresh processing method is the same as that of the above-described first and second modified examples except for the processing described in the third modified example.

The refresh processing method of the third modified example will be described together with the operation of the magnetic disk device 1. Application of the refresh processing to the second target sector SCaq of the first recording layer La1 of the disk DK1 will be described.

As shown in FIG. 3, FIG. 4, and FIG. 12, the adjustment unit 64 can adjust the weighting coefficient for each zone Z. For example, the adjustment unit 64 can adjust k2 that is a second weighting coefficient applied to the second zone Z2. When the refresh processing method is started, the adjustment unit 64 adjusts the second weighting coefficient k2 to a numerical value within the first range during the first period and adjusts the second weighting coefficient k2 to a numerical value within the second range during the second period.

When the second write of the data to the second adjacent sectors SCa(q−1) and SCa(q+1) is performed, the counter 62 counts the second write count N2 as k2 times.

The determination unit 65 applies a second write count threshold value to the second zone Z2. The determination unit 65 applies the first write count threshold value to the first zone Z1. Next, the determination unit 65 determines whether a second cumulative total of the second write count N2 counted by the counter 62 exceeds the second write count threshold value.

When the determination unit 65 determines that the second cumulative total has exceeded the second write count threshold value, under control of the MPU 60, the refresh processing unit 63 reads the second target data in the second target sector SCaq, rewrites the second target data to the second target sector SCaq, to refresh the second target sector SCaq, and resets the second write count N2.

Based on the above, the third modified example can obtain the same advantages as those of the above-described first and second modified examples.

The weighting coefficient can be set and the write count threshold value can also be set for each zone Z. In the third modified example, too, the ATI refresh processing can be performed by changing the conditions for each zone Z. For this reason, the first weighting coefficient k1 and the second weighting coefficient k2 may be different from each other. The first write count threshold value and the second write count threshold value may be different from each other. The magnetic disk device 1 and the refresh processing method capable of further efficiently rewriting the data can be thereby obtained.

### Fourth Modified Example

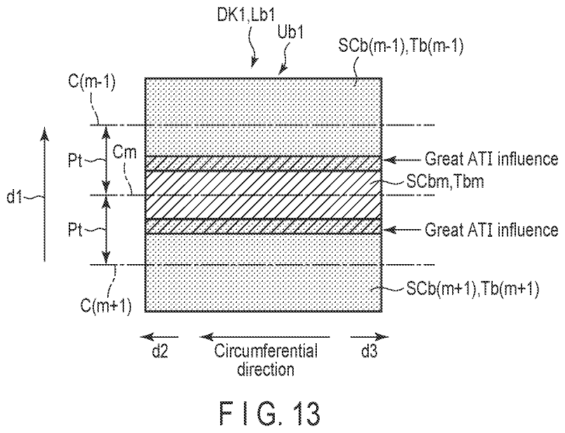

Next, a fourth modified example will be described. The magnetic disk device 1 is configured in the same manner as the above-described embodiment except for the configuration described in the fourth modified example. The refresh processing method is the same as that of the above-described embodiment except for the processing described in the fourth modified example. FIG. 13 is a schematic diagram showing three sectors SCb arranged in the radial direction d1 of the magnetic disk device 1, illustrating the opposite side of the three sectors SCa(m−1), SCam, and SCa(m+1) shown in FIG. 10.

In FIG. 13, hatch lines are drawn in the area where the write processing of the data for the sector SCbm is performed, and a dot pattern is drawn in the area where the data write processing for the sector SCb(m−1) is performed and the area where the data write processing for the sector SCb(m+1) is performed.

As shown in FIG. 13, the disk DK1 includes the tracks Tb(m−1), Tbm, and Tb(m+1) in the second recording layer Lb1 on the side opposite to the first recording layer La1. The track Tbm is located on the same cylinder as the first target track Tam and includes a sector SCbm. The track Tb(m−1) is located on the same cylinder as the first adjacent track Ta(m−1) and includes a sector SCb(m−1) adjacent to the sector SCbm in the radial direction d1. The track Tb(m+1) is located on the same cylinder as the first adjacent track Ta(m+1) and includes a sector SCb(m+1) adjacent to the sector SCbm in the radial direction d1.

The track Tbm includes a track center Cm, the track Tb(m−1) includes a track center C(m−1), and the track Tb(m+1) includes a track center C(m+1).

In the following descriptions, the track Tbm is referred to as a third target track Tbm, the track Tb(m−1) is referred to as a third adjacent track Tb(m−1), and the track Tb(m+1) is referred to as a third adjacent track Tb(m+1). The third adjacent track Tb(m+1) is a third inner adjacent track located inside the third target track Tbm. The third adjacent track Tb(m−1) is a third outer adjacent track located outside the third target track Tbm.

In addition, the sector SCbm is referred to as a third target sector SCbm, the sector SCb(m−1) is referred to as a third adjacent sector SCb(m−1), and the sector SCb(m+1) is referred to as a third adjacent sector SCb(m+1). The third adjacent sector SCb(m+1) is a third inner adjacent sector adjacent to the third target sector SCbm in the radial direction d1. The third adjacent sector SCb(m−1) is a third outer adjacent sector adjacent to the third target sector SCbm in the radial direction d1.

The disk DK1 in the fourth modified example is configured as described above.

Next, the refresh processing method of the fourth modified example will be described together with the operation of the magnetic disk device 1. Application of the refresh processing to the third target sector SCbm of the second recording layer Lb1 on the disk DK1 will be described. In the fourth modified example, the adjustment unit 64 applies the first weighting coefficient k1 to the head HD1 (first recording layer La1) and the head HD2 (second recording layer Lb1).

As shown in FIG. 3, FIG. 4, and FIG. 13, when the refresh processing method is started, the counter 62 counts the third write count N3 as k1 times, when third write of the data to the third adjacent sectors SCb(m−1) and SCb(m+1) is performed.

The determination unit 65 applies the third write count threshold value to the head HD2 (second recording layer Lb1). The determination unit 65 applies the first write count threshold value to the head HD1 (first recording layer La1). Next, the determination unit 65 determines whether a third cumulative total of the third write count N3 counted by the counter 62 exceeds the third write count threshold value.

When the determination unit 65 determines that the third cumulative total has exceeded the third write count threshold value, under control of the MPU 60, the refresh processing unit 63 reads the third target data in the third target sector SCbm, rewrites the third target data to the third target sector SCbm, to refresh the third target sector SCbm, and resets the third write count N3. When determining whether the third cumulative total exceeds the third write count threshold value, the adjustment unit 64 adjusts the first weighting coefficient k1 to a numerical value within the first range during the first period and adjusts the first weighting coefficient k1 to a numerical value within the second range during the second period.

Based on the above, the fourth modified example can obtain the same advantages as those of the above-described embodiment.

Since the first weighting coefficient k1 is common in a plurality of heads HD, the first weighting coefficient k1 is applied to each of the heads HD in the same manner when counting the first write count N1 and the third write count N3. However, the write count threshold value can be set for each head HD. In the fourth modified example, the ATI refresh processing can be performed by changing the conditions for each head HD. For this reason, the first write count threshold value and the third write count threshold value may be different from each other. For example, if the ATI influence caused by the head HD2 is greater than the ATI influence caused by the head HD1, the third write count threshold value may be set to be smaller than the first write count threshold value. The magnetic disk device 1 can thereby rewrite the data even more efficiently.

Then, when the ATI refresh processing is performed for the track of the first recording layer La1 and the track of the second recording layer Lb1 located on the same cylinder, the ATI refresh processing can be performed by changing the conditions.

### Fifth Modified Example

Next, a fifth modified example will be described. The magnetic disk device 1 is configured in the same manner as the above-described fourth modified example except for the configuration described in the fifth modified example. The refresh processing method is the same as that of the above-described embodiment except for steps described in the fifth modified example.

The refresh processing method of the fifth modified example will be described together with the operation of the magnetic disk device 1. Application of the refresh processing to the third target sector SCbm of the second recording layer Lb1 on the disk DK1 will be described. In the fifth modified example, the determination unit 65 applies the first write count threshold value to the head HD1 (first recording layer La1) and the head HD2 (second recording layer Lb1).

As shown in FIG. 3, FIG. 4, and FIG. 13, the adjustment unit 64 can adjust the weighting coefficient for each head HD. For example, the adjustment unit 64 can adjust k3 that is a third weighting coefficient applied to the head HD2 (second recording layer Lb1). When the refresh processing method is started, the adjustment unit 64 adjusts the third weighting coefficient k3 to a numerical value within the first range during the first period and adjusts the third weighting coefficient k3 to a numerical value within the second range during the second period.

When the third write of the data to the third adjacent sectors SCb(m−1) and SCb(m+1) is performed, the counter 62 counts the third write count N3 as k3 times.

The determination unit 65 applies the first write count threshold value to the head HD1 (first recording layer La1) and the head HD2 (second recording layer Lb1). Next, the determination unit 65 determines whether a third cumulative total of the third write count N3 counted by the counter 62 exceeds the first write count threshold value.

When the determination unit 65 determines that the third cumulative total has exceeded the first write count threshold value, under control of the MPU 60, the refresh processing unit 63 reads the third target data in the third target sector SCbm, rewrites the third target data to the third target sector SCbm, to refresh the third target sector SCbm, and resets the third write count N3.

Based on the above, the fifth modified example can obtain the same advantages as those of the above-described fourth modified example.

Since the first write count threshold value is common in the plurality of heads HD, the first wright count threshold value is applied in the same manner when determining the first cumulative total and the third cumulative total. However, the weighting coefficient can be set for each head HD. In the fifth modified example, too, the ATI refresh processing can be performed by changing the conditions for each head HD. For this reason, the first weighting coefficient k1 and the third weighting coefficient k3 may be different from each other. For example, if the ATI influence caused by the head HD2 is greater than the ATI influence caused by the first head HD1, the third weighting coefficient k3 may be set to be greater than the first weighting coefficient k1. The magnetic disk device 1 can thereby rewrite the data even more efficiently.

### Sixth Modified Example

Next, a sixth modified example will be described. The magnetic disk device 1 is configured in the same manner as the above-described fourth and fifth modified examples except for the configuration described in the sixth modified example. The refresh processing method is the same as that of the above-described fourth and fifth modified examples except for the steps described in the sixth modified example.

The refresh processing method of the sixth modified example will be described together with the operation of the magnetic disk device 1. Application of the refresh processing to the third target sector SCbm of the second recording layer Lb1 on the disk DK1 will be described.

As shown in FIG. 3, FIG. 4, and FIG. 13, the adjustment unit 64 can adjust the weighting coefficient for each head HD. For example, the adjustment unit 64 can adjust k3 that is a third weighting coefficient applied to the head HD2. When the refresh processing method is started, the adjustment unit 64 adjusts the third weighting coefficient k3 to a numerical value within the first range during the first period and adjusts the third weighting coefficient k3 to a numerical value within the second range during the second period.

When the third write of the data to the third adjacent sectors SCb(m−1) and SCb(m+1) is performed, the counter 62 counts the third write count N3 as k3 times.

The determination unit 65 applies the third write count threshold value to the head HD2. The determination unit 65 applies the first write count threshold value to the head HD1. Next, the determination unit 65 determines whether a third cumulative total of the third write count N3 counted by the counter 62 exceeds the third write count threshold value.

When the determination unit 65 determines that the third cumulative total has exceeded the third write count threshold value, under control of the MPU 60, the refresh processing unit 63 reads the third target data in the third target sector SCbm, rewrites the third target data to the third target sector SCbm, to refresh the third target sector SCbm, and resets the third write count N3.

Based on the above, the sixth modified example can obtain the same advantages as those of the above-described fourth and fifth modified examples.

The weighting coefficient can be set and the write count threshold value can also be set for each head HD. In the sixth modified example, too, the ATI refresh process can be performed under different conditions for each head HD. For this reason, the first weighting coefficient k1 and the third weighting coefficient k3 may be different from each other. The first write count threshold value and the third write count threshold value may be different from each other. The magnetic disk device 1 and the refresh processing method capable of further efficiently rewriting the data can be thereby obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. It is possible to combine two or more of the embodiment and modified examples with each other if needed.

For example, the above-described techniques may be applied to the shingled write recording magnetic disk device, and the hybrid recording magnetic disk device that selectively executes the conventional magnetic recording and the shingled write recording. For example, in the hybrid recording, a user data area U of the recording layer L includes a shingled write recording area on the inner circumferential side and a conventional magnetic recording area on the side outer than the shingled write recording area. The conventional magnetic recording area is often referred to as a conventional zone, and can be an area where frequently rewritten data such as system files and metadata are recorded.

What is claimed is:

1. A magnetic disk device comprising:
a disk including a first target track which includes a first target sector and a first adjacent track which includes a first adjacent sector adjacent to the first target sector in a radial direction, in a first recording layer;
a first head writing data to the first recording layer of the disk and reading data from the first recording layer; and
a control unit,
the control unit comprising:
an adjustment unit capable of adjusting k1 that is a first weighting coefficient;
a counter counting a first write count as the k1 times, when first write of data to the first adjacent sector is performed;
a determination unit determining whether a first cumulative total of the first write count counted by the counter exceeds a first write count threshold value; and
a refresh processing unit reading first target data in the first target sector, rewriting the first target data to the first target sector, to refresh the first target sector, and resetting the first write count counted by the counter, when the first cumulative total exceeds the first write count threshold value,
the adjustment unit adjusting the k1 to a numerical value within a first range during a first period which is a specific period after timing of first turning on power of the control unit, and adjusting the k1 to a numerical value within a second range during a second period after the first period has elapsed,
an upper limit of the numerical value within the second range being smaller than a lower limit of the numerical value within the first range.

2. The magnetic disk device of claim 1, wherein
the first adjacent track includes:
a first inner adjacent track located inside the first target track and including a first inner adjacent sector adjacent to the first target sector in the radial direction; and
a first outer adjacent track located outside the first target track and including a first outer adjacent sector adjacent to the first target sector in the radial direction, and
the counter counts the first write count as the k1 times, when first write of data to the first inner adjacent sector and the first outer adjacent sector is performed.

3. The magnetic disk device of claim 1, wherein
the adjustment unit adjusts the k1 to k1a during a first term of the first period, adjusts the k1 to k1b during a second term following the first term of the first period, and adjusts the k1 to k1x during the second period, where k1a>k1b>k1x.

4. The magnetic disk device of claim 1, wherein
the adjustment unit adjusts the k1 to a numerical value exceeding 1 during the first period and fixes the k1 to 1 during the second period.

5. The magnetic disk device of claim 1, wherein
when data is written to the first target sector before the first cumulative total exceeds the first write count threshold value, the refresh processing unit resets the first write count counted by the counter.

6. The magnetic disk device of claim 1, wherein
the disk further includes a second target track including a second target sector, a second adjacent track including a second adjacent sector adjacent to the second target sector in the radial direction, a first zone, and a second zone located inside the first zone, in the first recording layer,
the first target track is located in the first zone,
the second target track is located in the second zone,
the counter counts a second write count as the k1 times, when second write of data to the second adjacent sector is performed,
the determination unit applies the first write count threshold value to the first zone, applies a second write count threshold value to the second zone, and determines whether a second cumulative total of the second write count counted by the counter exceeds the second write count threshold value, and
the refresh processing unit reads second target data in the second target sector, rewrites the second target data to the second target sector, to refresh the second target sector, and resets the second write count counted by the counter, when the second cumulative total exceeds the second write count threshold value.

7. The magnetic disk device of claim 6, wherein
the first write count threshold value and the second write count threshold value are different from each other.

8. The magnetic disk device of claim 1, wherein
the disk further includes a second target track including a second target sector, a second adjacent track including a second adjacent sector adjacent to the second target sector in the radial direction, a first zone, and a second zone located inside the first zone, in the first recording layer,
the first target track is located in the first zone,
the second target track is located in the second zone,
the adjustment unit is capable of adjusting k2 that is a second weighting coefficient, adjusts the k2 to a numerical value within the first range during the first period, and adjusts the k2 to a numerical value within the second range during the second period,
the counter counts the second write count as the k2 times, when second write of data to the second adjacent sector is performed,
the determination unit applies the first write count threshold value to the first zone and the second zone, and determines whether a second cumulative total of the second write count counted by the counter exceeds the first write count threshold value, and
the refresh processing unit reads second target data in the second target sector, rewrites the second target data to the second target sector, to refresh the second target sector, and resets the second write count counted by the counter, when the second cumulative total exceeds the first write count threshold value.

9. The magnetic disk device of claim 8, wherein
the k1 and the k2 are different from each other.

10. The magnetic disk device of claim 1, wherein
the disk further includes a second target track including a second target sector, a second adjacent track including a second adjacent sector adjacent to the second target sector in the radial direction, a first zone, and a second zone located inside the first zone, in the first recording layer,
the first target track is located in the first zone,
the second target track is located in the second zone,
the adjustment unit is capable of adjusting k2 that is a second weighting coefficient, adjusts the k2 to a numerical value within the first range during the first period, and adjusts the k2 to a numerical value within the second range during the second period,
the counter counts the second write count as the k2 times, when second write of data to the second adjacent sector is performed,
the determination unit applies the first write count threshold value to the first zone, applies a second write count threshold value to the second zone, and determines whether a second cumulative total of the second write count counted by the counter exceeds the second write count threshold value, and
the refresh processing unit reads second target data in the second target sector, rewrites the second target data to the second target sector, to refresh the second target sector, and resets the second write count counted by the counter, when the second cumulative total exceeds the second write count threshold value.

11. The magnetic disk device of claim 10, wherein
the first write count threshold value and the second write count threshold value are different from each other.

12. The magnetic disk device of claim 10, wherein
the k1 and the k2 are different from each other.

13. The magnetic disk device of claim 1, further comprising:
a second head,
wherein
the disk includes a third target track including a third target sector and located on a same cylinder as the first target track, and a third adjacent track including a third adjacent sector adjacent to the third target sector in the radial direction, in a second recording layer on a side opposite to the first recording layer,
the second head writes data to the second recording layer of the disk and reads data from the second recording layer,
the counter counts a third write count as the k1 times, when third write of data to the third adjacent sector is performed,
the determination unit determines whether a third cumulative total of the third write count counted by the counter exceeds a third write count threshold value, and
the refresh processing unit reads third target data in the third target sector, rewrites the third target data to the third target sector, to refresh the third target sector, and resets the third write count counted by the counter, when the third cumulative total exceeds the third write count threshold value.

14. The magnetic disk device of claim 13, wherein
the first write count threshold value and the third write count threshold value are different from each other.

15. The magnetic disk device of claim 1, further comprising:
a second head,
wherein
the disk includes a third target track including a third target sector and located on a same cylinder as the first target track, and a third adjacent track including a third adjacent sector adjacent to the third target sector in the radial direction, in a second recording layer on a side opposite to the first recording layer,
the second head writes data to the second recording layer of the disk and reads data from the second recording layer,
the adjustment unit is capable of adjusting k3 that is a third weighting coefficient, adjusts the k3 to a numerical value within the first range during the first period, and adjusts the k3 to a numerical value within the second range during the second period,
the counter counts a third write count as the k3 times, when third write of data to the third adjacent sector is performed,
the determination unit determines whether a third cumulative total of the third write count counted by the counter exceeds the first write count threshold value, and
the refresh processing unit reads third target data in the third target sector, rewrites the third target data to the third target sector, to refresh the third target sector, and resets the third write count counted by the counter, when the third cumulative total exceeds the first write count threshold value.

16. The magnetic disk device of claim 15, wherein
the k1 and the k3 are different from each other.

17. The magnetic disk device of claim 1, further comprising:
a second head,
wherein
the disk includes a third target track including a third target sector and located on a same cylinder as the first target track, and a third adjacent track including a third adjacent sector adjacent to the third target sector in the radial direction, in a second recording layer on a side opposite to the first recording layer,
the second head writes data to the second recording layer of the disk and reads data from the second recording layer,
the adjustment unit is capable of adjusting k3 that is a third weighting coefficient, adjusts the k3 to a numerical value within the first range during the first period, and adjusts the k3 to a numerical value within the second range during the second period,
the counter counts a third write count as the k3 times, when third write of data to the third adjacent sector is performed,
the determination unit determines whether a third cumulative total of the third write count counted by the counter exceeds a third write count threshold value, and
the refresh processing unit reads third target data in the third target sector, rewrites the third target data to the third target sector, to refresh the third target sector, and resets the third write count counted by the counter, when the third cumulative total exceeds the third write count threshold value.

18. The magnetic disk device of claim 1, further comprising:
a housing which accommodates the disk and the first head and in which air exists.

19. A refresh processing method applied to a magnetic disk device comprising a disk including a first target track which includes a first target sector and a first adjacent track which includes a first adjacent sector adjacent to the first target sector in a radial direction, in a first recording layer, a first head writing data to the first recording layer of the disk and reading data from the first recording layer, and a control unit, the method comprising:
when a first weighting coefficient is set to k1,
counting a first write count as the k1 times, when first write of data to the first adjacent sector is performed;
determining whether the first cumulative total of the first write count exceeds the first write count threshold value;
when the first cumulative total exceeds the first write count threshold value, under control of the control unit, reading first target data in the first target sector, rewriting the first target data to the first target sector, to refresh the first target sector, and resetting the first write count; and
when determining whether the first cumulative total exceeds the first write count threshold value, adjusting the k1 to a numerical value within a first range during a first period which is a specific period after timing of first turning on power of the control unit, and adjusting the k1 to a numerical value within a second range during a second period after the first period has elapsed,
an upper limit of the numerical value within the second range being smaller than a lower limit of the numerical value within the first range.
